(19) United States
(12) Patent Application Publication
(10) Pub. No.: US 2025/0230917 A1
(43) Pub. Date: Jul. 17, 2025

(54) ILLUMINATOR COMPRISING BICONVEX LENS WITH TIR TEETH

(71) Applicant: Lumileds LLC, San Jose, CA (US)

(72) Inventors: Arjen Gerben van der Sijde, Eindhoven (NL); Nicola Bettina Pfeffer, Eindhoven (NL)

(73) Assignee: Lumileds LLC, San Jose, CA (US)

(21) Appl. No.: 19/095,328

(22) Filed: Mar. 31, 2025

Related U.S. Application Data
(63) Continuation of application No. PCT/US2023/033502, filed on Sep. 22, 2023.
(60) Provisional application No. 63/412,791, filed on Oct. 3, 2022.

(51) Int. Cl. F21V 5/04; F21V 7/00; F21Y 105/10; F21Y 115/10; G03B 15/05

(52) U.S. Cl. CPC F21V 5/045; F21V 7/0091; G03B 15/05; F21Y 2105/10; F21Y 2115/10

(57) ABSTRACT

A lens comprises a first surface and a second surface opposite the first surface. The first surface includes a first convex central refractive portion and a total internal reflection (TIR) portion peripheral to the first convex central portion. The second surface includes a second convex central refractive portion and a peripheral refractive portion having a curvature different from a curvature of the second convex central refractive portion. The first convex central refractive portion and the second convex central refractive portion are shaped to collimate or partially collimate light via refraction at the first convex central portion followed by refraction at the second convex central portion. The TIR portion and the peripheral refractive portion are shaped to collimate or partially collimate light by total internal reflection at the TIR portion followed by refraction at the peripheral refractive portion.

### CROSS-REFERENCE TO RELATED APPLICATIONS

This application is a continuation of PCT Application PCT/US2023/033502 filed Sep. 22, 2023, which claims benefit of priority to U.S. Provisional Patent Application 63/412,791 filed Oct. 3, 2022. Both of the above applications are incorporated herein by reference in their entirety.

### FIELD OF THE INVENTION

The present disclosure relates generally to illumination using light emitting diodes (LEDs) and/or phosphor converted LEDs (pcLEDs).

### BACKGROUND

The term “light emitting diode” as used in this description is intended to include laser diodes (e.g., vertical cavity surface emitting lasers, VCSELs) as well as light emitting diodes that are not lasers. The high efficiency of LEDs compared to conventional incandescent lightbulbs and fluorescent lights as well as improved manufacturing capability has led to their vastly increased use in a wide range of lighting applications. The compact nature, low power, and controllability of LEDs has likewise led to their use as light sources in a variety of electronic devices such as cameras and smart phones.

### SUMMARY

In one aspect of the invention, a lens comprises a first surface and a second surface opposite the first surface. The first surface includes a first convex central refractive portion and a total internal reflection (TIR) portion peripheral to the first convex central portion. The second surface includes a second convex central refractive portion and a peripheral refractive portion which may have a curvature different from a curvature of the second convex central refractive portion. The first convex central refractive portion and the second convex central refractive portion are shaped to collimate or partially collimate light via refraction at the first convex central portion followed by refraction at the second convex central portion. The TIR portion and the peripheral refractive portion are shaped to collimate or partially collimate light by total internal reflection at the TIR portion followed by refraction at the peripheral refractive portion.

In another aspect of the invention, an illumination system comprises an LED or pcLED array and a lens as summarized above arranged with the first surface of the lens facing the array to collimate or partially collimate light emitted by the array. The illumination system may comprise a controller configured to operate the LEDs or pcLEDs. The LEDs or pcLEDs may be independently controllable or controllable in groups and may be segments of a monolithic structure. The LEDs or pcLEDs may be or comprise microLEDs.

In another aspect of the invention, a mobile device comprises a camera, a flash illumination system, and a controller. The flash illumination system comprises a monolithic array of LEDs or pcLEDs and a lens as summarized above arranged with the first surface of the lens facing the array to collimate or partially collimate light emitted by the array. The controller may be configured to operate the LEDs or pcLEDs to adapt light emitted by the flash illumination system to a field of view of the camera. The LEDs or pcLEDs may be independently controllable or controllable in groups and may be segments of a monolithic structure. The LEDs or pcLEDs may be or comprise microLEDs.

These and other embodiments, features and advantages of the present invention will become more apparent to those skilled in the art when taken with reference to the following more detailed description of the invention in conjunction with the accompanying drawings that are first briefly described

### BRIEF DESCRIPTION OF THE DRAWINGS

FIG. 1A and FIG. 1B show cross-sectional side views of an example of an illumination system comprising an LED array or pcLED array and a lens. FIG. 1C shows an end-on (top) view of the illumination system of FIG. 1A and FIG. 1B.

FIG. 2 shows a top view of the LED or pcLED array in the example illumination system of FIG. 1A and FIG. 1B.

FIG. 3 shows an example of a camera and flash system.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention.

In an LED or pcLED based illumination system, a lens can collimate or at least partially focus light emitted from one or more LEDs or pcLEDs. Some illumination systems, such as a flash for a camera, can require that the collimated or at least partially focused light cover a relatively wide field of view (FOV). For example, for a smartphone-based camera and flash, in which the camera has a full-angle field of view, the camera flash can provide illumination that extends over the full-angle field of view of the camera. A typical full-angle field of view for a smartphone-based camera can be up to 120 degrees or larger.

Further, in mobile devices such as smart phones or tablets, it may be desirable to have cameras provide different fields of view, varying between 40° and 120° for instance for a smart phone. An illumination unit matching such a field of view should optimize light throughput while fitting into a limited volume. A lens used for such illumination does not need to have perfect imaging properties since resolution specifications are not as high as required for imaging applications. Efficiency may be preferred over traditional imaging quality characteristic performance parameters such as those based on a modulation transfer functions.

Typical refraction-based imaging lenses can be unsuitable for use in such illumination systems. For example, because an imaging lens is typically designed to form a high-quality image of a scene in the field of view of the imaging lens, such an imaging lens can be relatively large, relatively expensive, and may have relatively poor efficiency (e.g., relatively high loss due to reflection and/or scattering) at relatively high field of view angles.

In contrast with a typical imaging lens, an illumination system lens can be designed to direct as much of the LED or pcLED emitted light as possible (or as practical) into an illuminating beam that emerges from the illumination system lens. In particular, the imaging lens can utilize total internal reflection (TIR) to increase the efficiency (e.g. reduce or eliminate loss due to reflection and/or scattering) at relatively high field of view angles.

An illumination system, as described in detail below, can include an array of LEDs or pcLEDs and a lens that can substantially collimate or at least partially focus light emitted from the LEDs or pcLEDs in the array to produce emerging light. Optionally, the LEDs or pcLEDs are individually operable or operable in groups and the system comprises a controller that can individually control the LEDs or pcLEDs or control them in groups to provide adaptive illumination, that is, illumination that may be varied in intensity, color, direction, angular output, and/or spatial location depending for example on characteristics of objects or a scene to be illuminated. For example, such a system may provide illumination with an angular output adaptable to match a varying field of view of a camera. The lens, as described in detail below, can utilize total internal reflection to increase its efficiency at relatively high field of view angles.

Such adaptive illumination is also increasingly important for automotive road lighting applications, for example. In adaptive illumination applications the dimensions, especially the height of the light source and associated optics (e.g., lenses), may be an important design parameter.

In the illumination systems described herein, some of the light emitted from the array is emitted toward central portions of the lens and some of the light emitted from the array is emitted toward peripheral portions of the lens adjacent (optionally, surrounding) the central portions. The lens has a first surface that faces the array and a second surface opposite the first surface. The first surface includes a first convex central refractive portion and a peripheral TIR portion adjacent (optionally, surrounding) the central refractive portion. The second surface includes a second convex central refractive portion and a peripheral refractive portion adjacent (optionally, surrounding) the second convex central refractive portion. The peripheral refractive portion may have a curvature different from that of the second convex central refractive portion. For example, the peripheral refractive portion may have less curvature (i.e., be flatter) than the second convex central refractive portion.

The first and second convex central portions can substantially collimate light emitted toward the central portions of the lens via refraction at the first convex central refractive portion followed by refraction at the second convex central refractive portion. The peripheral TIR portion and the peripheral refractive portion can substantially collimate light emitted toward the peripheral portions of the lens via total internal reflection at the peripheral TIR portion followed by refraction at the peripheral refractive portion.

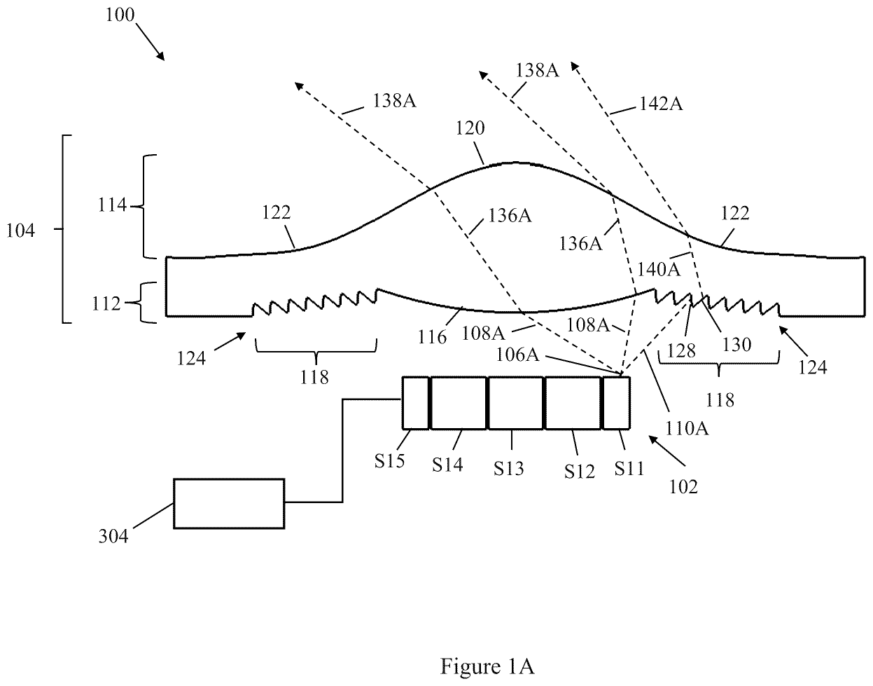

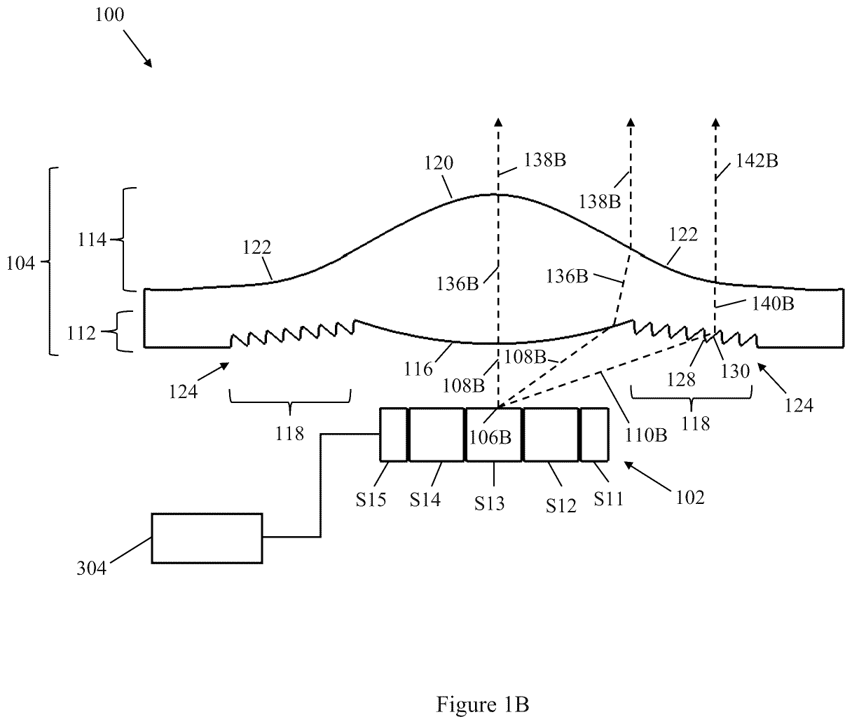

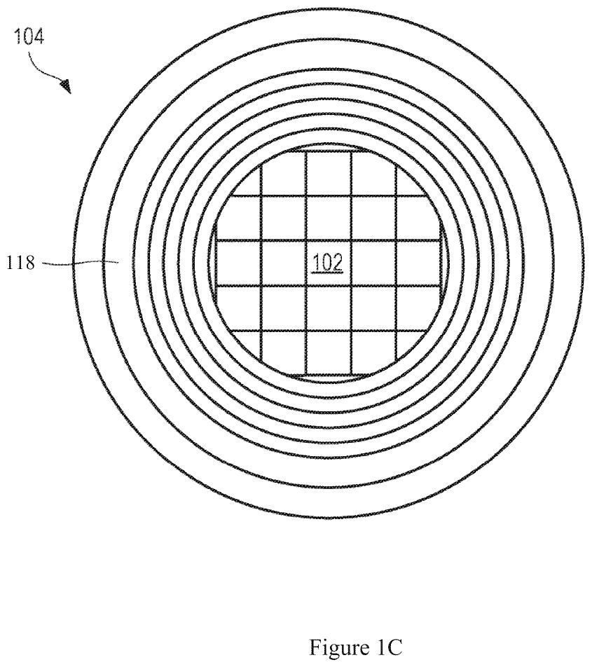

FIG. 1A and FIG. 1B show a cross-sectional side view of an example of an illumination system 100. FIG. 1C shows an end-on view. Illumination system 100 comprises an LED or pcLED array 102, a lens 104, and a controller 304 configured to control operation of the LEDs or pcLEDs in array 102.

In the illustrated example array 102 is a segmented monolithic device comprising independently operable LED segments S11, S12, S13, S14, and S15. In alternative variations array 102 may be formed from discrete LEDs or pcLEDs or from two or more segmented monolithic devices.

By “segmented monolithic device” this disclosure refers to a monolithic semiconductor diode structure in which trenches passing partially but not entirely through the semiconductor diode structure define electrically isolated segments. The electrically isolated segments remain physically connected to each other by portions of the semiconductor structure. For example, in such a monolithic structure the active region and a first semiconductor layer of a first conductivity type (n or p) on one side of the active region may be segmented, and a second unsegmented semiconductor layer of the opposite conductivity type (p or n) positioned on the opposite side of the active region from the first semiconductor layer. The second semiconductor layer may then physically and electrically connect the segmented structures to each other on one side of the active region, with the segmented structures otherwise electrically isolated from each other and thus separately operable as individual LEDs.

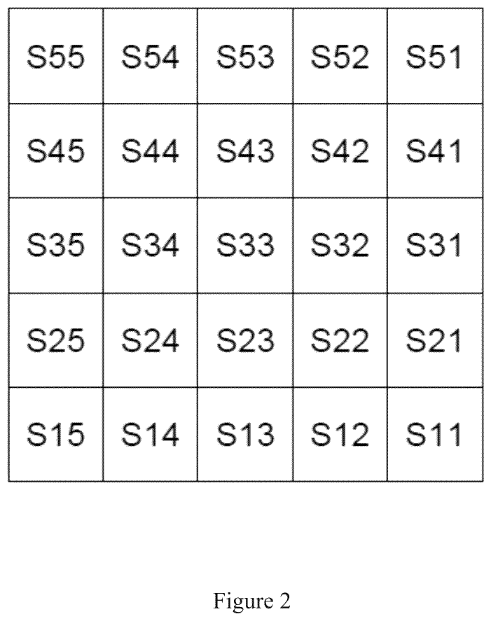

FIG. 2 shows a top view of LED or pcLED array 102, which in this example comprises 25 independently operable segments arranged in a square 5×5 array and identified by their location in the array by row and column as S (row, column) running from S11 to S55. More generally, array 102 may be for example a rectangular array or may approximate a non-rectangular (e.g., circular or oval) shape. Any suitable sized array may be used, for example a 3×3 array, a 5×5 array (as shown), a 7×7 array, or a 15×21 array. The LED or pcLED segments in the array can be of the same size, or of different sizes. For example, the central segment or segments could be chosen to be larger than peripheral segments. The array may have dimensions in the plane of the array of, for example, about 1.5 mm×1.5 mm to about 3 mm×3 mm.

The segments in array 102 may have dimensions in the plane of the array (e.g., side lengths) of, for example, less than or equal to 500 microns, less than or equal to 200 microns, less than or equal to 100 microns, less than or equal to 50 microns, or less than or equal to 5 microns. LEDs or pcLEDs having dimensions in the plane of the array of less than or equal to about 50 microns are typically referred to as microLEDs, and an array of such microLEDs may be referred to as a microLED array.

The segments in array 102 may be separated from their closest neighbors by, for example, 5 microns or more, for example about 20 microns. The segments may be positioned within a distance of each other sufficient to both present a substantially uniform visual appearance and to provide a substantially uniform light beam. This distance can be selected so that the segments are separated by no more than a Rayleigh limit distance calculated for a user at a normal distance from the light source.

Each segment in array 102 may be a single color, with different segments emitting different colors (e.g., some segments emitting white light and other segments emitting red light). Different color segments can be interleaved. Segments of the same color may be grouped. Groups of one color of segment may be interleaved with groups of other colors. Independent operation of the segments may allow the color of light emitted by the array to be tuned.

Each segment comprises a semiconductor light emitting diode, and optionally a wavelength converting structure that absorbs light emitted by the semiconducting light emitting diode and emits light of a longer wavelength (in which case the segment is a pcLED). The semiconductor light emitting diodes may be formed for example from II-VI, III-V, or other semiconductor material systems and may be configured to emit, for example, ultraviolet, visible, or infrared light, depending on the application.

The wavelength converting structures if present include one or more wavelength converting materials which may be, for example, conventional phosphors, ceramic phosphors, organic phosphors, quantum dots, organic semiconductors, II-VI or III-V semiconductors, II-VI or III-V semiconductor quantum dots or nanocrystals, dyes, polymers, or other materials that luminesce. The wavelength converting materials absorb light emitted by the LED and in response emit light of a longer wavelength. Phosphors or other wavelength converting materials may be dispersed as luminescent particles in a binder material such as a silicone, for example, to form a wavelength converting structure. A wavelength converting structure may be or comprise a sintered ceramic phosphor plate. The wavelength converting structure may include light scattering or light diffusing elements, such as for example TiO₂. The wavelength converting structures may be a monolithic element covering multiple or all semiconductor light emitting diodes in an array, or may be structured into separate segments, each attached to a corresponding semiconductor light emitting diode. Gaps between these separate segments of the wavelength conversion structure may be filled with optically reflective, scattering, or absorbing material to confine light emission from each segment to that segment only.

In operation of illumination system 100, individual segments in array 102 may be operated by controller 304 (FIGS. 1A-1B) to provide illumination adapted for a particular purpose, as described above. For example, illumination system 100 may provide illumination that varies by color and/or intensity across an illuminated scene or object, is aimed in a desired direction, and/or matches a field of view of a camera. The field of view illuminated by system 100 may be controlled by selecting the number and location of LEDs or pcLEDs in array 102 that are operated to provide the illumination. In case a small field of view is needed, for instance 40°, only the central LED segments might be needed, while for a large field of view (for instance) 120° all LED segments could be switched on.

For an application such as a flash, for example, the total emitted optical power of the LEDs may be, for example, about 0.1 W to about 10 W.

Referring again to FIGS. 1A-1C, lens 104 can substantially collimate light that is

emitted from array 102. In some examples, the lens 104 can have a focal plane, and the array 102 can be disposed at, substantially at, or proximate the focal plane of the lens 104. For the purposes of this document, the phrase “substantially at” is intended to signify that an element is placed to within typical fabrication and alignment tolerances. Such tolerances are readily known to one of ordinary skill in the art and can vary from application-to-application or system-to-system. Similarly, the term “proximate” is intended to signify that an element is placed to within 50%, 25%, 10%, or 5% of a focal length of the lens. The lens may have a focal length of for example about 0.25 mm to about 5 mm, or for example about 1 to about 2 mm. To blur (i.e., defocus) the image a bit, the lens may be advantageously placed at a distance from the array less than the focal length of the lens, for example at a distance as short as about 40% to about 50% of the lens focal length.

It is instructive to examine light emitted from a single location 106A (FIG. 1A) on array 102. For example, the lens 104 can collimate or substantially collimate the light from the single location 106A, such that light from the single location 106A on array 102 emerges from the lens 104 at a single output angle or a (relatively small range of output angles) and can form a beam that has a cross-sectional size that remains constant or generally constant as it propagates away from the lens 104. It will be understood that light emerging from a different location (e.g., 106B shown in FIG. 1B) on array 102 may also be collimated or substantially collimated and can also form a beam that has a cross-sectional size that remains constant or generally constant as it propagates away from the lens 104 but will emerge from the lens 104 at a different output angle (or relatively small range of output angles). Light emitted from the full surface area of array 102 may be considered to be a superposition of light emitted from individual locations on the surface area.

Consequently, the collimated output of light from the full surface area may be considered to be a superposition of beams of generally constant cross-sectional size, all propagating with different directions away from the lens 104. By controlling which portions of the full surface area emit light, and how bright such emission is, the system 100 can control which directions away from the lens 104 (e.g. which portions of a field of view of the lens 104) receive illuminating light and how much illuminating light is delivered. In other words, controlling which light-emitting diodes are electrically powered, how much current is delivered to each light-emitting diode, and how such quantities evolve over time, can determine a time-evolving angular distribution of light emerging from the lens 104. While discussion below involves emission from only a single location (106A or 106B) on array 102, it will be understood that emission from other locations on array 102 can simultaneously (and/or time-sequentially) contribute to the time-evolving angular distribution and/or the time-evolving full angular field of view output of the illumination system 100.

Referring now to FIG. 1A, the light emitted from location 106A on array 102 can have a central light portion 108A and peripheral light portion 110A. As explained below, the central light portion 108A can be collimated or substantially collimated via refraction at a central portion of the lens 104, while the peripheral light portion 110A can be collimated or substantially collimated via a combination of total internal reflection and refraction at a peripheral portion of the lens 104.

The lens 104 can have a first surface 112 configured to face array 102 and a second surface 114 opposite the first surface 112. The first surface 112 can include a first convex central refractive portion 116 and a first TIR portion 118 adjacent to the first convex central refractive portion 116. The second surface 114 can include a second convex central refractive portion 120 and a peripheral convex potion 122 adjacent to the second convex central portion 120. The first TIR portion 118 may surround the first convex central refractive portion 116. The peripheral convex portion 122 may surround the second convex central refractive portion 120.

The first convex central refractive portion 116 and the second convex central refractive portion 120 can be shaped to substantially collimate the central light portion 108A via refraction at the first convex central refractive portion 116 followed by refraction at the second convex central refractive portion 120. Using such a biconvex configuration can allow the lens 104 to be thinner than comparable plano-convex or meniscus (convex-concave) configurations.

In some examples, the first convex central refractive portion 116 and the second convex central refractive portion 120 can each have a radius of curvature, R, as determined by the following equation:

$$tan \frac{θ}{2} = \sqrt{2} \frac{n - 1}{n} \frac{x}{R} ,$$

where quantity θ is an angular full field of view (such that θ equaling 180 degrees corresponds to a field of view extending over a full angular range on one side of a plane), quantity n is a refractive index of the lens 104, and quantity x is a length of the array of light-emitting diodes (such as a full length along an edge of the array, a half-length along an edge of the array, a full length of a diagonal of the array, or a half-length of a diagonal of the array). In some examples, quantity R can be greater than or equal to quantity x/\sqrt{2}. For these conditions, for a refractive index of 1.5 and purely spherical convex surfaces, the largest field of view that can be handled by the lens 104 is about 70 degrees. The field of view can be increased, beyond that can be attained by purely spherical surfaces, by imparting a non-zero conic constant to the first convex central portion 116 and the second convex central portion 120. For example, the conic constant of one or both of the first convex central portion 116 and the second convex central portion 120 can be less than or equal to −0.5.

In some examples, the first convex central refractive portion 116 can have a radius of curvature between about 0.5 mm and about 3.0 mm and can have a conic constant less than or equal to −0.5. In some examples, the second convex central refractive portion 120 can have a radius of curvature between about 0.5 mm and about 3.0 mm and can have a conic constant less than or equal to −0.5. In some examples, using these numerical values can accommodate fields of view of about 80 degrees to about 120 degrees.

Array 102 can be rectangular or square, for example. Array 102 may for example include a first length along a first edge of array 102, a second length along a second edge of the array 102 that is adjacent to the first edge of array 102, and a diagonal length extending diagonally across array 102. The first length and the second length may for example be less than an outer diameter of the first convex central refractive portion 116 and less than an outer diameter of the second convex central refractive portion 120. The diagonal length for example be greater than the outer diameter of the first convex central refractive portion 116 and greater than the outer diameter of the second convex central refractive portion 120.

A central axis of the lens 104 may extend through a center of the first convex central refractive portion 116 and a center of the second convex central refractive portion 120. The lens 104 may for example be rotationally symmetric about the central axis.

Still referring to FIG. 1A, the TIR portion 118 and the peripheral refractive portion 122 can be shaped to substantially collimate the peripheral light portion 110 via total internal reflection at the TIR portion 118 and refraction at the peripheral refractive portion 122. In some examples, the TIR portion 118 can have a cross-section, taken in a plane that includes the central axis, that includes a plurality of serrations 124. In some examples, the peripheral refractive portion 122 can have a cross-section, taken in the plane, that that has a curvature different from (e.g., less than) that of central convex refractive portion 120. Serrations 124 can allow the lens 104 to be thinner than if the serrations were not present, such as to achieve the same lensing effect. Peripheral refractive portion 122 may improve imaging by lens 104 compared to a lens in which refractive portion 122 is replaced by an additional TIR portion.

Each of serrations 124 can include an apex and a pair of opposing sides 128, 130 that each extend from the apex toward the second surface 114 of the lens 104. The pair of opposing sides can be angled such that peripheral light portion 110A enters the lens 104 via refraction at a first opposing side 128 of the pair of opposing sides and is directed toward the second peripheral portion 122 via total internal reflection at the second opposing side 130 of the pair of opposing sides. In some examples, the plurality of first serrations 124 can include apexes that lie on a virtual surface that is concave when viewed in the cross-section.

The first convex central refractive portion 116 can refract the central light portions 108A toward the second convex central refractive portion 120 as central internal light 136A. The second convex central refractive portion 120 can refract the central internal light 136A out of the lens 104 to form central exiting light 138A. The TIR portion 118 can reflect the peripheral light portions 110A toward the peripheral refractive portion 122 as peripheral internal light 140A. The peripheral refractive portion 122 can refract the peripheral internal light 140A to form peripheral exiting light 142A that exits the lens 104 and is substantially parallel to the central exiting light 138A.

Referring now to FIG. 1B, the light emitted from location 106B on array 102 can have central light portions 108B and peripheral light portions 110B. The first convex central refractive portion 116 can refract the central light portions 108B toward the second convex central refractive portion 120 as central internal light 136B. The second convex central refractive portion 120 can refract the central internal light 136B out of the lens 104 to form central exiting light 138B. The TIR portion 118 can reflect the peripheral light portions 110B toward the peripheral refractive portion 122 as peripheral internal light 140B. The peripheral refractive portion 122 can refract the peripheral internal light 140B to form peripheral exiting light 142B that exits the lens 104 and is substantially parallel to the central exiting light 138B.

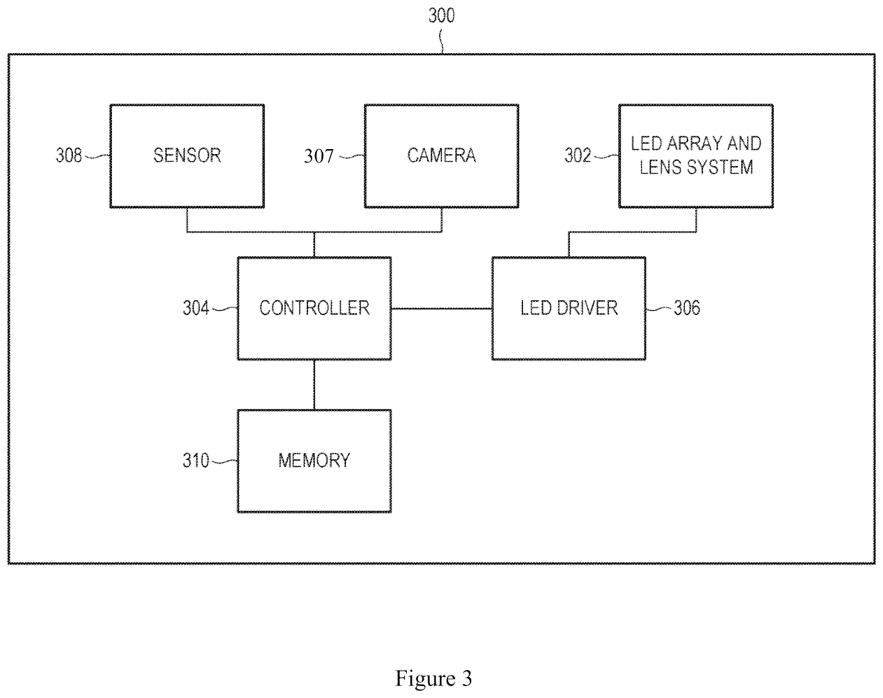

Referring again to FIGS. 1A-1B, controller 304 provides power to and controls operation of the LEDs or pcLEDs in array 102, for example to provide adaptive illumination as described above. In some examples, controller 304 can select from one of a specified plurality of subsets of the LEDs or pcLEDs, the subsets corresponding to different angular distributions (e.g., fields of view) of the light exiting lens 104. Controller 304 is discussed in further detail below with regard to FIG. 3.

FIG. 3 schematically illustrates an example of a camera and flash system 300. The system 300 may for example be part of a communication or computing device, such as a smart phone, a tablet, a laptop computer, for example. The system 300 may for example be included as part of another device, such as a digital camera or smart phone. System 300 comprises an LED or pcLED array and lens system 302, which may be or comprise an (e.g., adaptive) illumination system as described above in which LEDs or pcLEDs in the array may be individually operable or operable as groups. In operation of the camera flash system, illumination from some or all of the LEDs or pcLEDs in array and lens system 302 may be adjusted-deactivated, operated at full intensity, or operated at an intermediate intensity. The array may be a monolithic array, or comprise one or more monolithic arrays, as described above. The array may be a microLED array, as described above.

Flash system 300 also comprises an LED driver 306 that is controlled by a controller 304, such as for example a microprocessor. Controller 304 may also be coupled to a camera 307 and to sensors 308 and operate in accordance with instructions and profiles stored in memory 310. Camera 307 and LED or pcLED array and lens system 302 may be controlled by controller 304 to, for example, match the illumination provided by system 302 (i.e., the field of view of the illumination system) to the field of view of camera 307, or to otherwise adapt the illumination provided by system 302 to the scene viewed by the camera as described above. Sensors 308 may include, for example, positional sensors (e.g., a gyroscope and/or accelerometer) and/or other sensors that may be used to determine the position and orientation of system 500.

This disclosure is illustrative and not limiting. Further modifications will be apparent to one skilled in the art in light of this disclosure and are intended to fall within the scope of the appended claims.

What is claimed is:

1. A lens comprising:
a first surface and a second surface opposite the first surface, the first surface including a first convex central refractive portion and a total internal reflection (TIR) portion peripheral to the first convex central portion, the second surface including a second convex central refractive portion and a peripheral refractive portion having a curvature different from a curvature of the second convex central refractive portion,
the first convex central refractive portion and the second convex central refractive portion being shaped to collimate or partially collimate light via refraction at the first convex central portion followed by refraction at the second convex central portion,
the TIR portion and the peripheral refractive portion being shaped to collimate or partially collimate light by total internal reflection at the TIR portion followed by refraction at the peripheral refractive portion.

2. The lens of claim 1, wherein:
a central axis of the lens extends through a center of the first convex central refractive portion and a center of the second convex refractive central portion; and
the TIR portion has a cross-section, taken in a plane that includes the central axis, that includes a plurality of serrations.

3. The lens of claim 2, wherein:
each serration includes an apex and a pair of opposing sides that each extend from the apex toward the second surface of the lens;
the pair of opposing sides is angled such that light that enters the lens via refraction at a first side of the pair of opposing sides is directed toward the refractive peripheral portion via total internal reflection at a second side of the pair of opposing sides and refracted out of the lens by the peripheral refractive portion.

4. The lens of claim 2, wherein the plurality of serrations includes apexes that lie on a virtual surface that is concave when viewed in the cross-section.

5. The lens of claim 2, wherein the plurality of serrations includes apexes that lie on a virtual surface that is generally planar when viewed in the cross-section.

6. The lens of claim 1, wherein:
the lens is circular;
the TIR portion surrounds the first convex central refractive portion; and
and the peripheral refractive portion surrounds the second convex central refractive portion.

7. The lens of claim 1, wherein the lens is rotationally symmetric about a central axis that extends through a center of the first convex central refractive portion and a center of the second convex refractive central portion.

8. The lens of claim 1, wherein:
the first convex central refractive portion has a radius of curvature between about 0.5 mm and about 3.0 mm and has a conic constant less than or equal to −0.5; and
the second convex central portion has a radius of curvature between about 0.5 mm and about 3.0 mm and has a conic constant less than or equal to −0.5.

9. An illumination system comprising:
an array of LEDs or pcLEDs; and
the lens of claim 1 arranged with its first surface facing the array to collimate or partially collimate light emitted by the array.

10. The illumination system of claim 9, wherein the LEDs or pcLEDs are independently controllable.

11. The illumination system of claim 9, wherein each LED or pcLED is a segment of a monolithic structure.

12. The illumination system of claim 11, wherein each LED or pcLED is or comprises a microLED.

13. The illumination system of claim 9, wherein each LED or pcLED has a largest dimension in the plane of the array of less than or equal to 500 microns.

14. The illumination system of claim 9, wherein each LED or pcLED has a largest dimension in the plane of the array of less than or equal to 100 microns.

15. The illumination system of claim 9, wherein each LED or pcLED has a largest dimension in the plane of the array of less than or equal to 50 microns.

16. The illumination system of claim 9, comprising a controller configured to power the LEDs or pcLEDs.

17. A mobile device comprising:
a camera;
a flash illumination system comprising:
a monolithic array of independently controllable LEDs or pcLEDs;
the lens of claim 1 arranged with its first surface facing the array to collimate or partially collimate light emitted by the array; and
a controller configured to operate the LEDs or pcLEDs to adapt light emitted by the flash illumination system to a field of view of the camera.

18. The mobile device of claim 17, wherein the controller is configured to operate the LEDs or pcLEDs to match a field of view of the flash illumination system to a field of view of the camera.

19. The mobile device of claim 17, wherein each LED or pcLED has a largest dimension in the plane of the array of less than or equal to 100 microns.

20. The mobile device of claim 17, wherein each LED or pcLED is or comprises a microLED.
